(19) United States
(12) Patent Application Publication
(10) Pub. No.: US 2015/0028393 A1
(43) Pub. Date: Jan. 29, 2015

(54) SOLID-STATE IMAGING DEVICE AND LINE SENSOR

(71) Applicant: Kabushiki Kaisha Toshiba, Minato-ku (JP)

(72) Inventor: Ken TOMITA, Iwate (JP)

(73) Assignee: Kabushiki Kaisha Toshiba, Minato-ku (JP)

(21) Appl. No.: 14/188,843

(22) Filed: Feb. 25, 2014

(30) Foreign Application Priority Data
Jul. 25, 2013 (JP) 2013-154543

(51) Int. Cl. H01L 27/146

(52) U.S. Cl. CPC H01L 27/14623
USPC 257/222

(57) ABSTRACT

Certain embodiments provide a solid-state imaging device including a pixel portion, a charge storage portion, a first transfer gate portion transferring charge from the pixel portion to the charge storage portion, and a second transfer gate portion transferring the charge from the charge storage portion to the charge detection portion. The pixel portion includes a light sensing layer and a shield layer shielding the light sensing layer. The charge storage portion includes a charge storage layer shielding the charge storage layer. At least one of the shield layer for light sensing layer and the shield layer for charge storage layer includes a concave part to expose a part of the light sensing layer adjacent to the first transfer gate portion or a part of the charge storage layer adjacent to the second transfer gate portion.

### CROSS REFERENCE TO RELATED APPLICATIONS

This application is based upon and claims the benefit of priority from the prior Japanese Patent Application No. 2013-154543 filed in Japan on Jul. 25, 2013; the entire contents of which are incorporated herein by reference.

### FIELD

Embodiments described herein relate generally to a solid-state imaging device and a line sensor.

### BACKGROUND

As a conventional solid-state imaging device, a solid-state imaging device having charge storage portion between respective pixel portions and a charge detection portion in order to make it possible to change over a resolution is known.

In this solid-state imaging device, a light sensing layer which generates charge depending upon a light sensing amount is provided in the pixel portion. A charge storage layer which stores charge generated in the light sensing layer is provided in the charge storage portion. Furthermore, a shield layer for suppressing a dark current is provided on each of a surface of the light sensing layer and a surface of the charge storage layer.

In a case where, for example, a position of the shield layer relative to the light sensing layer deviates from a predetermined position due to a manufacture error, a dip or a barrier is generated in an electric potential between the shield layer and a transfer gate portion which transfers charge from the pixel portion to the charge storage portion. As a result, it is necessary to cause a voltage applied to the transfer gate portion in order to transfer charge to become large. This poses a problem that a voltage margin of the voltage applied to the transfer gate portion is small. In addition, it becomes difficult to satisfy a voltage margin for mass production required for each of products, resulting in a problem of a lowered yield.

### BRIEF DESCRIPTION OF THE DRAWINGS

FIG. 1 is a plane view schematically showing a solid-state imaging device according to a first embodiment;

FIG. 2 is a sectional view of the solid-state imaging device taken along a dot-dash line A-A′ in FIG. 1;

FIG. 3 is a sectional view showing a modification of a second pixel portion;

FIG. 4 is an enlarged plane view showing a second pixel portion in the solid-state imaging device according to the first embodiment;

FIG. 5 is an enlarged plane view showing a second charge storage portion in the solid-state imaging device according to the first embodiment;

FIGS. 6A and 6B are diagrams for explaining an electric potential formed in a solid-state imaging device according to an embodiment, FIG. 6A is a sectional view of the solid-state imaging device shown in FIG. 2, and FIG. 6B is a diagram showing an electric potential at the section shown in FIG. 6A;

FIG. 7 is an enlarged plane view showing a principal part of a conventional solid-state imaging device;

FIG. 8 is a diagram showing relations between a distance from one end of an N type impurity layer to one end of a P type impurity layer and a variation amount of an electric potential between the N type impurity layer and a transfer gate portion, in the solid-state imaging device according to the first embodiment and the conventional solid-state imaging device;

FIG. 9 is an enlarged plane view of a second pixel portion in a solid-state imaging device according to a second embodiment;

FIG. 10 is an enlarged plane view of a second charge storage portion in the solid-state imaging device according to the second embodiment;

FIG. 11 is a diagram showing relations between a distance from one end of an N type impurity layer to one end of a P type impurity layer and a variation amount of an electric potential between the N type impurity layer and a transfer gate portion, in the solid-state imaging devices according to the first and second embodiments and the conventional solid-state imaging device;

FIG. 12 is a sectional view corresponding to FIG. 2, in a solid-state imaging device according to a third embodiment;

FIG. 13 is an enlarged plane view showing a second charge storage portion and its periphery in the solid-state imaging device according to the third embodiment;

FIG. 14 is an enlarged plane view showing an offset gate portion and its periphery in the solid-state imaging device according to the third embodiment;

FIG. 15 is a plane view schematically showing a principal part of a solid-state imaging device according to a fourth embodiment;

FIG. 16 is a sectional view of the solid-state imaging device taken along a dot-dash line B-B′ in FIG. 15;

FIG. 17 is an enlarged plane view of a pixel portion in a solid-state imaging device according to a fourth embodiment;

FIG. 18 is an oblique view showing a line sensor to which the solid-state imaging device according to the first embodiment is applied; and

FIG. 19 is a circuit block diagram of one solid-state imaging device applied to the line sensor shown in FIG. 18.

### DETAILED DESCRIPTION

Certain embodiments provide a solid-state imaging device including a pixel portion, a charge storage portion, a first transfer gate portion, a charge detection portion, and a second detection portion. The pixel portion includes a light sensing layer provided on a surface of a semiconductor substrate to generate charge depending upon a light sensing amount of incident light and a shield layer for the light sensing layer provided so as to shield the light sensing layer. The charge storage portion includes a charge storage layer provided on the surface of the semiconductor substrate to store the charge generated in the pixel portion and a shield layer for the charge storage layer provided so as to shield the charge storage layer. The first transfer gate portion reads out the charge from the pixel portion and transfers the charge to the charge storage portion. The charge stored in the charge storage portion is transferred to the charge detection portion. The charge detection portion generates a voltage drop depending upon a charge amount of the transferred charge. The second transfer gate portion reads out the charge stored in the charge storage portion, and transfers the charge to the charge detection portion. At least one of the shield layer for light sensing layer and the shield layer for charge storage layer includes a concave part to expose a part of the light sensing layer adjacent to the first transfer gate portion or apart of the charge storage layer adjacent to the second transfer gate portion.

Certain embodiments provide a solid-state imaging device including a plurality of pixel portions arranged in a row form, a plurality of charge storage portions, a plurality of first transfer gate portions, a charge detection portion, a plurality of second transfer gate portions, and an offset gate portion. The plurality of charge storage portions are arranged in a row form parallel to a direction of arrangement of the plurality of pixel portions. The plurality of first transfer gate portions read out the charges from the plurality of pixel portions and transfer the charges to the plurality of charge storage portions. The charges stored in the plurality of charge storage portions are transferred to the charge detection portion. The charge detection portion generates a voltage drop depending upon charge amounts of the transferred charges. The plurality of second transfer gate portions read out the charges stored in the plurality of charge storage portions and transfer the charges to the charge detection portion. The offset gate portion takes a shape having alongside along a lengthwise direction which is a direction parallel to the direction of arrangement of the plurality of pixel portion and a short side along a direction substantially perpendicular to the lengthwise direction. The offset gate portion is provided between the plurality of second transfer gate portions and the charge detection portion so as to be close to the plurality of second transfer gate portions at the long side and the short sides, and is applied with a predetermined constant voltage. In the solid-state imaging device, each of the plurality of pixel portions includes a light sensing layer provided on a surface of a semiconductor substrate to generate charge depending upon a light sensing amount of incident light and a shield layer for the light sensing layer provided so as to shield the light sensing layer. Each of the plurality of charge storage portions includes a first charge storage layer provided on the surface of the semiconductor substrate to store the charge generated in the pixel portion and a shield layer for the charge storage layer provided so as to shield the first charge storage layer. At least one of the shield layer for light sensing layer and the shield layer for charge storage layer includes a concave part to expose a part of the light sensing layer adjacent to the first transfer gate portion or a part of the first charge storage layer adjacent to the second transfer gate portion.

Certain embodiments provide a solid-state imaging device including a pixel portion, a charge detection portion, and a transfer gate portion. The pixel portion includes a light sensing layer provided on a surface of a semiconductor substrate to generate charge depending upon a light sensing amount of incident light and a shield layer for the light sensing layer provided so as to shield the light sensing layer. The shield layer for light sensing layer has a concave part to expose a part of the light sensing layer adjacent to the transfer gate portion. The charge stored in the pixel portion is transferred to the charge detection portion. The charge detection portion generates a voltage drop depending upon a charge amount of the transferred charge. The transfer gate portion reads out the charge stored in the pixel portion and transfers the charge to the charge detection portion.

Certain embodiments provide a line sensor including a circuit substrate, a plurality of solid-state imaging devices, a light guide plate, and a lens array. The plurality of solid-state imaging devices are arranged in a straight line form on a surface of the circuit substrate. The light guide plate is disposed above the surface of the circuit substrate and emits light toward a subject. The lens array is disposed above the surface of the circuit substrate. The lens array condenses the light reflected by the subject to the plurality of solid-state imaging devices. In the line sensor, each of the plurality of solid-state imaging devices includes a pixel portion, a charge storage portion, a first transfer gate portion, a charge detection portion, and a second transfer gate portion. The pixel portion includes a light sensing layer provided on a surface of a semiconductor substrate to generate charge depending upon a light sensing amount of incident light and a shield layer for the light sensing layer provided so as to shield the light sensing layer. The charge storage portion includes a charge storage layer provided on the surface of the semiconductor substrate to store the charge generated in the pixel portion and a shield layer for the charge storage layer provided so as to shield the charge storage layer. The first transfer gate portion reads out the charge from the pixel portion and transfers the charge to the charge storage portion. The charge stored in the charge storage portion is transferred to the charge detection portion. The charge detection portion generates a voltage drop depending upon a charge amount of the transferred charge. The second transfer gate portion reads out the charge stored in the charge storage portion, and transfers the charge to the charge detection portion. At least one of the shield layer for light sensing layer and the shield layer for charge storage layer includes a concave part to expose a part of the light sensing layer adjacent to the first transfer gate portion or apart of the charge storage layer adjacent to the second transfer gate portion.

Hereafter, solid-state imaging devices and line sensors according to embodiments will be described.

### First Embodiment

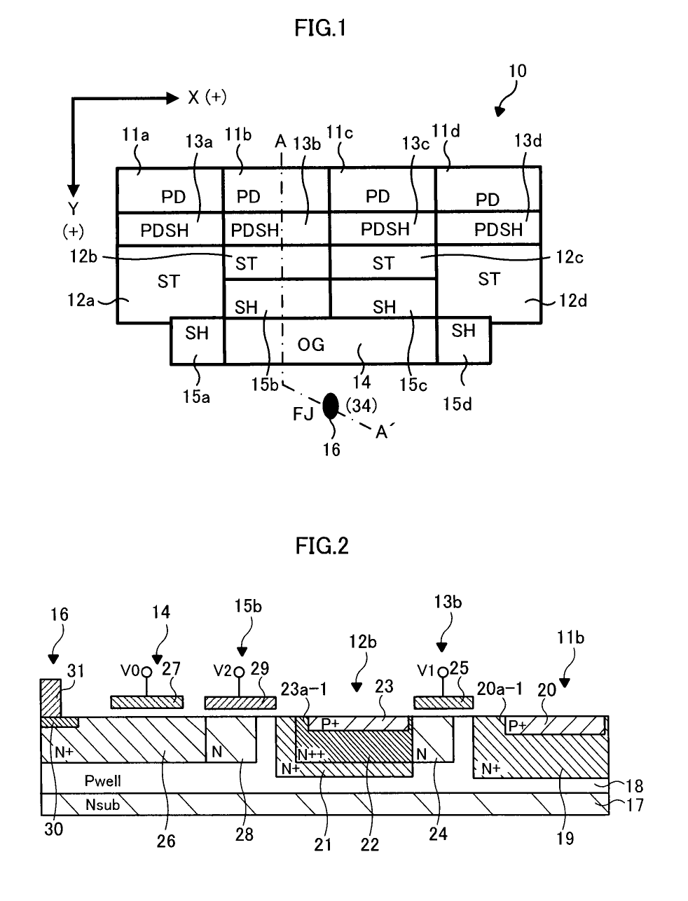

FIG. 1 is a plane view schematically showing a principal part of a solid-state imaging device 10 according to the present embodiment. By the way, in the solid-state imaging device 10 according to the present embodiment, a plurality of cells each having four pixels as one cell are arranged in one row. However, the embodiment is not restricted to a solid-state imaging device of four pixels per cell type. The number of pixels included in one cell may be at least four, and may be, for example, eight.

In the solid-state imaging device 10 shown in FIG. 1, four pixel portions (PD) 11a, 11b, 11c and 11d are arranged in a row. In the ensuing description, the four pixel portions 11a, 11b, 11c and 11d are referred to as first pixel portion 11a, second pixel portion 11b, third pixel portion 11c and fourth pixel portion 11d in order beginning with the left side of the drawing. Furthermore, a direction parallel to the row of the pixel portions 11a, 11b, 11c and 11d is referred to as X direction. A direction away from the pixel portion 11a toward the pixel portion 11d is referred to as X(+) direction. A direction perpendicular to the X direction is referred to as Y direction. A direction away from the pixel portions 11a, 11b, 11c and 11d is referred to as Y(+) direction. In other words, the four pixel portions 11a, 11b, 11c and 11d are arranged along the X direction toward the X(+) direction in the cited order. By the way, the pixel portions 11a, 11b, 11c and 11d are provided so as to have a lengthwise direction of the pixel portions 11a, 11b, 11c and 11d in the X direction.

Each of the pixel portions 11a, 11b, 11c and 11d senses light (incident light) with which the area is irradiated, and generates charge of an amount depending upon the light sensing amount.

By the way, each of the actual pixel portions 11a, 11b, 11c and 11d takes the shape of a polygon having a lengthwise direction in the X direction. The shape is a polygonal shape close to a rectangle having the lengthwise direction in the X direction. In the above-described FIG. 1 and drawings described hereafter, therefore, each of the pixel portions 11a, 11b, 11c and 11d is shown as rectangular-shaped. In the ensuing description, it is supposed that each of the pixel portions 11a, 11b, 11c and 11d takes the shape of a rectangle.

In a position away from the first pixel portion 11a in the Y(+) direction, a first charge storage portion (ST) 12a is provided. In the same way, in a position away from the second pixel portion 11b in the Y(+) direction, a second charge storage portion (ST) 12b is provided. In a position away from the third pixel portion 11c in the Y(+) direction, a third charge storage portion (ST) 12c is provided. In a position away from the fourth pixel portion 11d in the Y(+) direction, a fourth charge storage portion (ST) 12d is provided. These charge storage portions 12a, 12b, 12c and 12d are provided in one row along the arrangement direction (X direction) of the pixel portions 11a, 11b, 11c and 11d, toward the X(+) direction in the cited order.

Charges generated in corresponding pixel portions 11a, 11b, 11c and 11d are transferred to the charge storage portions 12a, 12b, 12c and 12d, respectively. The charge storage portions store the transferred charges temporarily. Changeover of resolution becomes possible by providing such areas.

First transfer gate portions (PDSHs) 13a, 13b, 13c and 13d are provided between the pixel portions 11a, 11b, 11c and 11d and the charge storage portions 12a, 12b, 12c and 12d which correspond to each other, respectively.

The first transfer gate portions 13a, 13b, 13c and 13d read out charges generated in the pixel portions 11a, 11b, 11c and 11d, and transfer the charges to the charge storage portions 12a, 12b, 12c and 12d respectively corresponding to the pixel portions 11a, 11b, 11c and 11d, respectively.

In a position away from the second charge storage portion 12b and the third charge storage portion 12c in the Y(+) direction, an offset gate portion (OG) 14, which takes a shape having a lengthwise direction in the X direction, is provided.

A predetermined constant voltage V0 (for example, V0=0 V) is applied to the offset gate portion 14. Since the constant voltage is applied in this way, the offset gate portion 14 improves a read precision of a signal voltage in a charge detection portion 16, which will be described later. If the read precision of the signal voltage in the charge detection portion 16 is within an allowable range, the offset gate portion 14 may not be provided.

By the way, the actual offset gate portion 14 takes the shape of a polygon having a lengthwise direction in the X direction. The shape is a polygonal shape close to a rectangle. In the above-described FIG. 1 and drawings described hereafter, therefore, the offset gate portion 14 is shown as rectangular-shaped. In the ensuing description, it is supposed that the offset gate portion 14 takes the shape of a rectangle.

Second transfer gate portions (SH) 15b and 15c are provided between a first long side, which forms the shape of the offset gate portion 14, and the second charge storage portion 12b and the third charge storage portion 12c, respectively. Furthermore, a second transfer gate portion (SH) 15a is provided between a first short side, which forms the shape of the offset gate portion 14, and the first charge storage portion 12a. A second transfer gate portion (SH) 15d is provided between a second short side of the offset gate portion 14, which opposes the first short side, and the fourth charge storage portion 12d.

In other words, the second charge storage portion 12b and the third charge storage portion 12c are connected to the long side of the offset gate portion 14 via the second transfer gate portions 15b and 15c, respectively. The first charge storage portion 12a and the fourth charge storage portion 12d are connected to the short sides of the offset gate portion 14 via the second transfer gate portions 15a and 15d, respectively.

The second transfer gate portions 15a, 15b, 15c and 15d read out charges stored in the charge storage portions 12a, 12b, 12c and 12d, respectively, and transfer the charges to a charge detection portion 16, which will be described later, via the offset gate portion 14.

A charge detection portion (FJ) 16, which is a floating junction, is provided in a position adjacent to a second long side, which opposes the first long side forming the shape of the offset gate portion 14.

The charge detection portion 16 is an area which generates a voltage drop depending upon a charge amount of charge transferred to this area and reads out the generated voltage drop as a signal voltage.

FIG. 2 is a sectional view of the solid-state imaging device 10 taken along a dot-dash line A-A′ in FIG. 1. By the way, in FIG. 2, a section passing through the second pixel portion 11b and the second charge storage portion 12b is shown as an example of a sectional view of the solid-state imaging device 10 according to the present embodiment.

As shown in FIG. 2, the second pixel portion 11b, the first transfer gate portion 13b, the second charge storage portion 12b, the second transfer gate portion 15b, the offset gate portion 14 and the charge detection portion 16 are provided in a P type well layer 18, which is provided on, for example, an N type semiconductor substrate 17.

In the second pixel portion 11b, a light sensing layer 19 is provided on a surface of the well layer 18. The light sensing layer 19 is, for example, an N+ type impurity layer.

A shield layer for light sensing layer 20, which shields the light sensing layer 19, is provided on a surface of the light sensing layer 19. The shield layer for light sensing layer 20 is, for example, a P+ type impurity layer.

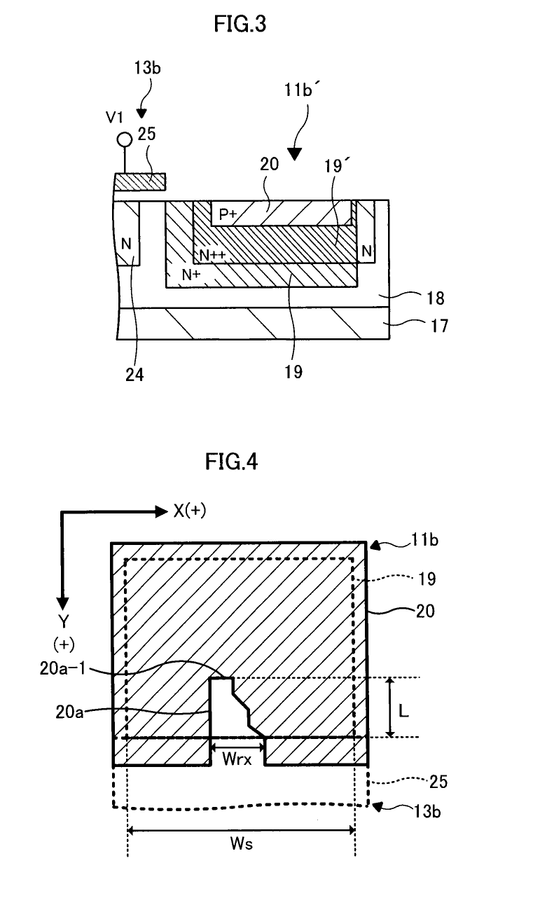

By the way, FIG. 3 shows a modification of the second pixel portion. Ina second pixel portion 11b′, a second light sensing layer 19′, which is, for example, an N++ type impurity layer, may be provided away from the first transfer gate portion 13b in a part of the light sensing layer 19.

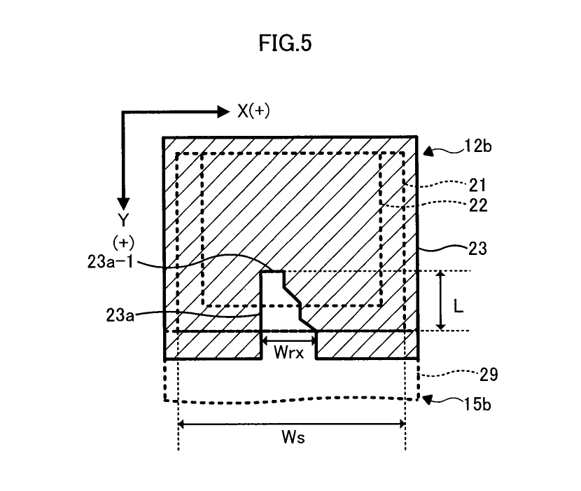

FIG. 4 is an enlarged plane view of the second pixel portion 11b. By the way, in FIG. 4, the light sensing layer 19 and a first transfer electrode 25, which will be described later, are shown by dashed lines.

As shown in FIG. 4, the shield layer for light sensing layer 20 takes a shape of a polygon, which is nearly a rectangle, corresponding to a shape of the light sensing layer 19. The shield layer for light sensing layer 20 has a concave part 20a on one side adjacent to the first transfer gate portion 13b having the first transfer electrode 25. The concave part 20a takes a shape in which a length Wrx (width) along the X(+) direction spreads toward the Y(+) direction.

The shield layer for light sensing layer 20 having such a concave part 20a covers the light sensing layer 19 so as to expose a part of the light sensing layer 19 from inside of the concave part 20a. The shield layer for light sensing layer 20 is provided so as to cause a partial area adjacent to the concave part 20a to jut out into the first transfer gate portion 13b.

For example, in a case where a width Ws of the light sensing layer 19 is 10 μm, the shield layer for light sensing layer 20 is provided in some cases so as to cause a distance L between one end of the light sensing layer 19 and a bottom side 20a-1 of the concave part 20a (hereafter, the distance L is referred to as distance L between one end of the N type impurity layer and one end of the P type impurity layer) to become 0.8 μm.

By the way, it is possible to expand a voltage margin of a voltage applied to the first transfer gate portion 13b and prevent the yield from falling by providing the concave part 20a in the shield layer for light sensing layer 20. The reason will be described later.

In the second charge storage layer 12b shown in FIG. 2, a first charge storage layer 21 is provided in a plane form on the surface of the well layer 18 so as to be adjacent to the second transfer gate portion 15b. Furthermore, a second charge storage layer 22 is provided on a part of a surface of the first charge storage layer 21 so as to be away from the second transfer gate portion 15b. The first charge storage layer 21 is, for example, an N+ type impurity layer that is higher in concentration than the N+ type light sensing layer 19. The second charge storage layer 22 is for example, an N++ type impurity layer that is higher in concentration than the first charge storage layer 21.

A shield layer for charge storage layer 23 is provided on a surface of the second charge storage layer 22 to partially jut out into the first charge storage layer 21. The shield layer for charge storage layer 23 is an impurity layer which shields at least the second charge storage layer 22, and is, for example, a P+ type impurity layer.

By the way, it is also possible to adjust (raise) an electric potential in the second charge storage portion 12b by adjusting (lowering) a concentration of the shield layer for charge storage layer 23.

FIG. 5 is an enlarged plane view showing the second charge storage portion 12b. By the way, in FIG. 5, the first and second charge storage layers 21 and 22 and a second transfer electrode 29, which will be described later, are shown by dashed lines.

As shown in FIG. 5, the shield layer for charge storage layer 23 takes a shape of a polygon, which is nearly a rectangle, corresponding to shapes of the first and second charge storage layers 21 and 22. In the same way as the shield layer for light sensing layer 20 shown in FIG. 4, the shield layer for charge storage layer 23 has a concave part 23a on one side adjacent to the second transfer gate portion 15b having the second transfer electrode 29. In the same way as the concave part 20a of the shield layer for light sensing layer 20, the concave part 23a also takes a shape in which a length Wrx (width) along the X(+) direction spreads toward the Y(+) direction.

The shield layer for charge storage layer 23 having such a concave part 23a covers the first and second charge storage layers 21 and 22 so as to expose parts of the first and second charge storage layers 21 and 22 from inside of the concave part 23a. The shield layer for charge storage layer 23 is provided so as to cause a partial area adjacent to the concave part 23a to jut out into the second transfer gate portion 15b.

For example, in a case where a width Ws of the first charge storage layer 21 is 10 μm, the shield layer for charge storage layer 23 is provided in some cases so as to cause a distance L between one end of the first charge storage layer 21 and a bottom side 23a-1 of the concave part 23a, i.e., the distance L between one end of the N type impurity layer and one end of the P type impurity layer to become 0.8 μm.

By the way, it is possible to expand a voltage margin of a voltage applied to the second transfer gate portion 15b and prevent the yield from falling by providing the concave part 23a in the shield layer for charge storage layer 23. The reason will be described later.

It is preferable that the second charge storage layer 22 is provided in the second charge storage portion 12b as described above. However, the second charge storage layer 22 is not an impurity layer that must be formed necessarily.

In the first transfer gate portion 13b shown in FIG. 2, a first transfer impurity layer 24 is provided on the surface of the well layer 18. On the surface of the well layer 18, the first transfer impurity layer 24 is provided so as to be away from the light sensing layer 19 and be in contact with the second charge storage layer 22. The first transfer impurity layer 24 is, for example, an N type impurity layer that is lower in concentration than the first charge storage layer 21. The first transfer impurity layer 24 is an impurity layer for favorably transferring charge in the first transfer gate portion 13b. If a transfer efficiency of charge in the first transfer gate portion 13b is within an allowable range, therefore, the first transfer impurity layer 24 may not be provided.

By the way, the first transfer impurity layer 24 can be provided in a lump together with the second charge storage layer 22 by providing the second charge storage layer 22 to cause a part of an N type impurity layer to jut out into the first transfer gate portion 13b when providing the second charge storage layer 22.

The first transfer electrode 25 is provided on the surface of the well layer 18 including a surface of the first transfer impurity layer 24. As for the first transfer electrode 25, a depth of an electric potential right under the first transfer electrode 25 is controlled by applying a predetermined voltage V1 to the first transfer electrode 25.

In the offset gate portion 14, an offset gate layer 26 is provided on the surface of the well layer 18. The offset gate layer 26 is, for example, an N+ type impurity layer, and is provided in a wide range including the offset gate portion 14 and the charge detection portion 16.

An offset gate electrode 27 is provided on a part of a surface of the offset gate layer 26. A predetermined constant voltage V0 (for example, V0=0 V) is applied to the offset gate electrode 27 to fix an electric potential in the offset gate portion 14 at an electric potential deeper than at least that of the second charge storage portion 12b. By applying the constant voltage in this way, a variation of an electric potential in the charge detection portion 16 caused by a variation of the electric potential in the second transfer gate portion 15b is suppressed and a voltage readout precision in the charge detection portion 16 is improved.

In the second transfer gate portion 15b, a second transfer impurity layer 28 is provided on the surface of the well layer 18. On the surface of the well layer 18, the second transfer impurity layer 28 is provided so as to be away from the first charge storage layer 21 and be in contact with the offset gate layer 26. The second transfer impurity layer 28 is, for example, an N type impurity layer that is close in impurity concentration to the first transfer impurity layer 24. In the same way as the first transfer impurity layer 24, the second transfer impurity layer 28 is an impurity layer for favorably transferring charge in the second transfer gate portion 15b. If a transfer efficiency of charge is within an allowable range, therefore, the second transfer impurity layer 28 may not be provided in the second transfer gate portion 15b as well in the same way as the first transfer gate portion 13b.

The second transfer electrode 29 is provided on the surface of the well layer 18 including a surface of the second transfer impurity layer 28. As for the second transfer electrode 29, a depth of an electric potential right under the second transfer electrode 29 is controlled by applying a predetermined voltage V2 to the second transfer electrode 29.

In the charge detection portion 16, a charge detection layer 30 is provided on the surface of the offset gate layer 26 provided in the charge detection portion 16. The charge detection layer 30 is, for example, an N++ type impurity layer that is higher in concentration than the offset gate layer 26. A read electrode 31 for reading out a voltage drop generated in the charge detection layer 30 as a signal voltage is provided on a part of a surface of the charge detection layer 30. If charge is stored in the charge detection layer 30, the electric potential in the charge detection portion 16 becomes a predetermined voltage depending upon the stored amount of charge. This voltage is read out as a signal voltage by the read electrode 31.

Heretofore, the sectional structure of the solid-state imaging device according to the present embodiment has been described. Each of a sectional structure passing through the third pixel portion 11c and the third charge storage portion 12c, a sectional structure passing through the first pixel portion 11a and the first charge storage portion 12a, and a sectional structure passing through the fourth pixel portion 11d and the fourth charge storage portion 12d is similar to the structure shown in FIG. 2.

Furthermore, the shield layer for light sensing layer 20 in each of the first, third and fourth pixel portions 11a, 11c and 11d has a structure similar to that shown in FIG. 4. The shield layer for charge storage layer 23 in each of the first, third and fourth charge storage portions 12a, 12c and 12d also has a structure similar to that shown in FIG. 5.

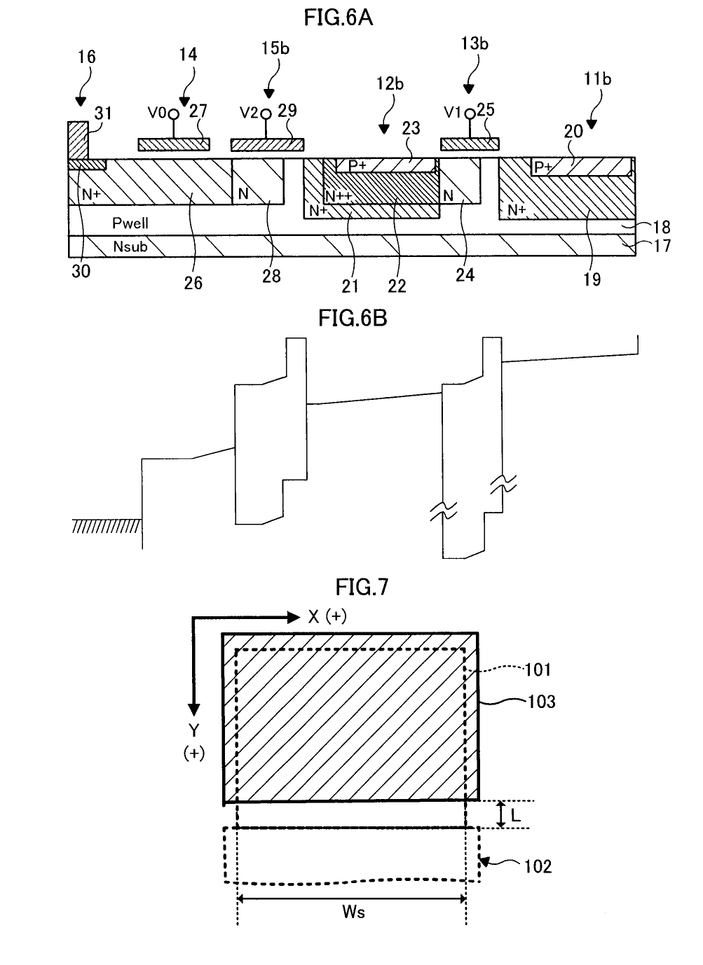

An electric potential at the section shown in FIG. 2 of the solid-state imaging device 10 provided as described above will now be described. FIGS. 6A and 6B are diagrams for explaining an electric potential formed in the solid-state imaging device 10. FIG. 6A is the sectional view of the solid-state imaging device 10 shown in FIG. 2. FIG. 6B is a diagram showing an electric potential at the section shown in FIG. 6A. By the way, a lower location in FIG. 6B indicates a deeper electric potential.

As shown in FIG. 6A, the light sensing layer 19 is provided in the second pixel portion 11b. The first charge storage layer 21 and the second charge storage layer 22 are provided in the second charge storage portion 12b. The light sensing layer 19 and the first and second charge storage layers 21 and 22 are away from each other. Furthermore, as shown in FIG. 6B, the second pixel portion 11b and the second charge storage portion 12b are made deeper in electric potential than the first transfer gate portion 13b between them.

In the second charge storage portion 12b, the first charge storage layer 21 and the second charge storage layer 22 are provided to be higher in concentration than the light sensing layer 19 in the second pixel portion 11b. As shown in FIG. 6B, therefore, the second charge storage portion 12b becomes deeper in electric potential than the second pixel portion 11b.

In addition, in the second charge storage portion 12b, the second charge storage layer 22 that is higher in concentration than the first charge storage layer 21 is provided on the surface of the first charge storage layer 21 so as to be away from the second transfer gate portion 15b. As shown in FIG. 6B, therefore, the electric potential in the second charge storage portion 12b becomes deeper as the location advances from the first transfer gate portion 13b to the second transfer gate portion 15b.

By the way, the first transfer impurity layer 24 is provided in the first transfer gate portion 13b. As shown in FIG. 6B, the electric potential in the first transfer gate portion 13b becomes deeper stepwise as the location advances from the second pixel portion 11b toward the second charge storage portion 12b, by providing the impurity layer 24. Charge transfer in the first transfer gate portion 13b is made favorable by such an electric potential.

Furthermore, as shown in FIG. 6A, the first charge storage layer 21 and the second charge storage layer 22 are provided in the second charge storage portion 12b, and the offset gate layer 26 is provided in the offset gate portion 14 and the charge detection portion 16. The first charge storage layer 21 and the offset gate layer 26 are away from each other. Furthermore, the second charge storage portion 12b and the offset gate portion 14 are made deeper in electric potential than the second transfer gate portion 15b disposed between them.

In the offset gate portion 14, the offset gate electrode 27 is provided on a part of the surface of the of f set gate layer 26. The predetermined constant voltage V0 (for example, V0=0 V) is applied to the offset gate electrode 27 to fix the electric potential in the offset gate portion 14 to a position deeper than that of the second charge storage portion 12b. Furthermore, as shown in FIG. 6B, the offset gate portion 14 is made deeper in electric potential than the second charge storage portion 12b.

By the way, the second transfer impurity layer 28 is provided in the second transfer gate portion 15b. As shown in FIG. 6B, the electric potential in the second transfer gate portion 15b becomes deeper stepwise as the location advances from the second charge storage portion 12b toward the offset gate portion 14, by providing the impurity layer 28. Charge transfer in the second transfer gate portion 15b is made favorable by such an electric potential.

Furthermore, in the charge detection portion 16, the charge detection layer 30 that is higher in concentration than the offset gate layer 26 is provided on the surface of the offset gate layer 26. Therefore, the charge detection portion 16 becomes deeper in electric potential than the offset gate portion 14. As a result, charge transferred to the offset gate portion 14 concentrate into the charge detection portion 16.

Hereafter, operation of the solid-state imaging device 10 will be described with reference to FIGS. 6A and 6B.

If light is incident on the second pixel portion 11b, charge is generated in the light sensing layer 19 by photoelectric conversion. The generated charge is stored in the second pixel portion 11b because the electric potential in the first transfer gate portion 13b becomes a barrier.

If the first transfer gate portion 13b is made deeper in electric potential than the second pixel portion 11b by applying the predetermined voltage V1 to the first transfer electrode 25 in the first transfer gate portion 13b, the charge generated in the second pixel portion 11b is transferred in the first transfer gate portion 13b and arrives at the second charge storage portion 12b. The transferred charge is stored in the second charge storage portion 12b because the electric potential in the second transfer gate portion 15b becomes a barrier.

If the second transfer gate portion 15b is made deeper in electric potential than the second charge storage portion 12b by applying the predetermined voltage V2 to the second transfer electrode 29 in the second transfer gate portion 15b, the charge stored in the second charge storage portion 12b is transferred in the second transfer gate portion 15b and arrives at the offset gate portion 14. Finally, the charge concentrates into the charge detection portion 16.

If the charge concentrates into the charge detection portion 16, a voltage drop depending upon the amount of charge stored in this part is generated. This voltage drop is read out as a signal voltage by the read electrode 31. The solid-state imaging device 10 forms an image on the basis of the signal voltage read out in this way.

By the way, the electric potential in the second transfer gate portion 15b varies because of transfer of charge as described above. If the charge detection portion 16 were connected to the second transfer gate portion 15b, therefore, the electric potential in the charge detection portion 16 would also vary according to the variation of the electric potential in the second transfer gate portion 15b. If the electric potential in the charge detection portion 16 varied, the readout precision of the signal voltage would fall.

On the other hand, in the present embodiment, the offset gate portion 14 having a fixed electric potential is provided between the second transfer gate portion 15b and the charge detection portion 16. Even if the electric potential in the second transfer gate portion 15b varies in this case, variation of the electric potential in the charge detection portion 16 is suppressed because the electric potential in the offset gate portion 14 is fixed. As a result, the readout precision of the signal voltage is improved. Because of such a reason, the constant voltage is applied to the offset gate portion 14.

In the solid-state imaging device 10 operating in this way, it is possible to expand voltage margins of voltages applied to the first and second transfer gate portions 13a to 13d and 15a to 15d and prevent the yield from falling by providing the concave parts 20a and 23a in the shield layer for light sensing layer 20 and the shield layer for charge storage layer 23, respectively, as shown in FIG. 4 and FIG. 5. Hereafter, the reason will be described while comparing the shield layer for light sensing layer 20 and the shield layer for charge storage layer 23 with the shield layer for light sensing layer and the shield layer for charge storage layer in the conventional solid-state imaging device.

FIG. 7 is an enlarged plane view of a pixel portion or a charge storage layer in the conventional solid-state imaging device. By the way, in the ensuing description, an N type impurity layer (an area indicated by a dashed line in FIG. 7) means a light sensing layer or a charge storage layer in the conventional solid-state imaging device. A P type impurity layer (an area indicated by a solid line in FIG. 7) means a shield layer for such an N type impurity layer. Furthermore, as shown in FIG. 7, an N type impurity layer 101 in the conventional solid-state imaging device is provided in contact with a transfer gate portion 102 (a part corresponding to the first transfer gate portions 13a to 13d or the second transfer gate portions 15a to 15d in the solid-state imaging device according to the present embodiment). Furthermore, a P type impurity layer 103 is provided away from the transfer gate portion 102.

For example, in a case where a width of the N type impurity layer 101 is 10 μm, ideally the P type impurity layer 103 is provided so as to cause a distance L between a first end of the N type impurity layer 101 and a first end of the P type impurity layer 103 to become 0.1 μm. In the case where the P type impurity layer 103 is provided in this way, neither a barrier nor a dip is generated in an electric potential between the first end of the N type impurity layer 101 and the transfer gate portion 102.

If the distance L between the first end of the N type impurity layer 101 and the first end of the P type impurity layer 103 becomes smaller than 0.1 μm due to, for example, a manufacture error, a barrier is generated in the electric potential between the first end of the N type impurity layer 101 and the transfer gate portion 102. If the distance L between the first end of the N type impurity layer 101 and the first end of the P type impurity layer 103 becomes larger than 0.1 μm, a dip is generated in the electric potential between the first end of the N type impurity layer 101 and the transfer gate portion 102.

In the conventional solid-state imaging device in which the pixel portion and the charge storage portion each taking the shape of nearly a rectangle are provided to cause the lengthwise direction of the pixel portion and the charge storage portion to be in a direction (X direction) perpendicular to the transfer direction of charge, the width Ws of the N type impurity layer 101 is long. Even if the distance L deviates from an ideal value only slightly, therefore, an area of the N type impurity layer 101 exposed between the P type impurity layer 103 and the transfer gate portion 102 varies largely. In the conventional solid-state imaging device, therefore, a barrier and a dip tend to be caused in the electric potential by a relative position deviation between the N type impurity layer 101 and the P type impurity layer 103.

On the other hand, in the solid-state imaging device 10 according to the present embodiment, the shield layer for light sensing layer 20 having the concave part 20a is provided so as to expose the light sensing layer 19 only from the inside of the concave part 20a as shown in FIG. 4. Even if the light sensing layer 19 and the shield layer for light sensing layer 20 are provided to deviate from ideal positions due to, for example, a manufacture error, therefore, a variation of an area of the light sensing layer 19 exposed between the shield layer for light sensing layer 20 and the first transfer gate portions 13a to 13d can be suppressed. Therefore, it is possible to prevent a barrier or a dip from being generated in the electric potential between the light sensing layer 19 and the first transfer gate portions 13a to 13d. By the way, for the same reason, it is possible to prevent a barrier or a dip from being generated in the electric potential between the first charge storage layer 21 and the second transfer gate portions 15a to 15d.

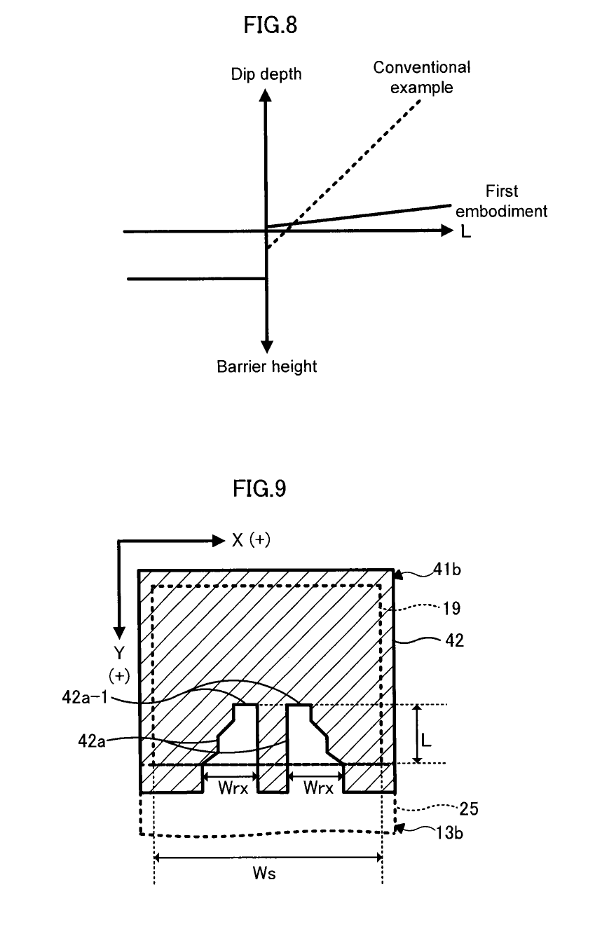

FIG. 8 is a diagram showing relations between the distance L from the first end of the N type impurity layer to the first end of the P type impurity layer and a variation amount of an electric potential between the N type impurity layer and the transfer gate portion, in the solid-state imaging device 10 according to the present embodiment and the conventional solid-state imaging device. The foregoing description is summarized in FIG. 8.

As shown in FIG. 8, inclination of a straight line (indicated by a dashed line in FIG. 8) indicating relations between the distance L and the variation amount of the electric potential in the conventional solid-state imaging device becomes large. In other words, a barrier or a dip tends to occur in the electric potential between the N type impurity layer 101 and the transfer gate portion 102. When transferring charge from an area including the N type impurity layer to the transfer gate portion 102, therefore, it is necessary to apply a high voltage to the transfer gate portion 102. Therefore, a voltage margin of the voltage applied to the transfer gate portion 102 becomes small. Furthermore, in a case where the voltage margin is small, a voltage margin demanded for each product cannot be satisfied and the yield falls.

On the other hand, in the solid-state imaging device 10 according to the present embodiment, inclination of a straight line (indicated by a solid line in FIG. 8) indicating relations between the distance L and the variation amount of the electric potential can be made smaller as compared with the conventional solid-state imaging device. In other words, it is possible to prevent a barrier or a dip from occurring in an electric potential between the light sensing layer 19 and the first transfer gate portion 13a to 13d and the electric potential between the first charge storage layer 21 and the second transfer gate portion 15a to 15d. As a result, a voltage applied to each of the transfer gate portions 13a to 13d and 15a to 15d can be made low when transferring charge from the pixel portions 11a to 11d to the first transfer gate portions 13a to 13d and when transferring charge from the charge storage portions 12a to 12d to the second transfer gate portions 15a to 15d. Voltage margins of voltages applied to the transfer gate portions 13a to 13d and 15a to 15d can be expanded. Furthermore, it is facilitated to satisfy a voltage margin demanded for each product and the yield is improved.

In the solid-state imaging device 10 according to the present embodiment, the concave parts 20a and 23a are provided in the shield layer for light sensing layer 20 and the shield layer for charge storage layer 23, respectively, as described heretofore. Therefore, voltage margins of the voltages applied to the transfer gate portions 13a to 13d and 15a to 15d can be expanded and the yield can be improved. Furthermore, especially since the voltage margin can be expanded, voltages applied to the transfer gate portions 13a to 13d and 15a to 15d can be made low and the charge transfer speed can be made fast.

In addition, in the solid-state imaging device 10 according to the present embodiment, the concave parts 20a and 23a are provided so as to cause each of the width Wrx of the concave part 20a in the shield layer for light sensing layer 20 and the width Wrx of the concave part 23a in the shield layer for charge storage layer 23 to spread toward the Y(+) direction, i.e., toward the charge transfer direction. Therefore, each of the electric potential in the light sensing layer 20 exposed from the concave part 20a and the electric potential in the first and second charge storage layers 21 and 22 exposed from the concave part 23a becomes deeper toward the charge transfer direction due to a narrow channel effect in the light sensing layer 20 exposed from the concave part 20a and a narrow channel effect in the first and second charge storage layers 21 and 22 exposed from the concave part 23a. As a result, the charge transfer efficiency in each area can be improved.

By the way, in the present embodiment, the concave parts 20a and 23a are provided in the shield layer for light sensing layer 20 and the shield layer for charge storage layer 23, respectively. Even in a case where the concave part 20a is provided only in the shield layer for light sensing layer 20 and the concave part 23a is not provided in the shield layer for charge storage layer 23, the voltage margin of the voltage applied to the first transfer gate portions 13a to 13d can be expanded and the yield can be improved. Furthermore, especially since the voltage margin can be expanded, the voltage applied to the first transfer gate portions 13a to 13d can be made low and the charge transfer speed can be made fast. In addition, the efficiency of charge transfer from the pixel portions 11a to 11d to the first transfer gate portions 13a to 13d can be improved. In the same way, even in a case where the concave part 23a is provided only in the shield layer for charge storage layer 23 and the concave part 20a is not provided in the shield layer for light sensing layer 20, the voltage margin of the voltage applied to the second transfer gate portions 15a to 15d can be expanded and the yield can be improved. Furthermore, especially since the voltage margin can be expanded, the voltage applied to the second transfer gate portions 15a to 15d can be made low and the charge transfer speed can be made fast. In addition, the efficiency of charge transfer from the charge storage portions 12a to 12d to the second transfer gate portions 15a to 15d can be improved.

In second and third embodiments described hereafter as well, concave parts are provided in both the shield layer for light sensing layer and the shield layer for charge storage layer in the same way as the first embodiment. However, the concave part may be provided only in the shield layer for light sensing layer, or the concave part may be provided only in the shield layer for charge storage layer.

### Second Embodiment

A solid-state imaging device according to a second embodiment will now be described. A general structure of the solid-state imaging device according to the second embodiment is similar to the structure shown in FIG. 1 and FIG. 2. Operation is also similar to the operation described with reference to FIG. 6. Therefore, description concerning them will be omitted. Hereafter, parts in which the solid-state imaging device according to the second embodiment is different from the first solid-state imaging device 10 according to the first embodiment will be described.

FIG. 9 is an enlarged plane view of a second pixel portion 41b in the solid-state imaging device according to the second embodiment. As shown in FIG. 9, the solid-state imaging device according to the second embodiment is the same as the solid-state imaging device 10 according to the first embodiment in that a shield layer for light sensing layer 42 takes the shape of a polygon that is nearly a rectangle corresponding to the shape of the light sensing layer 19. However, the solid-state imaging device according to the second embodiment is different from the solid-state imaging device 10 according to the first embodiment in that the shield layer for light sensing layer 42 has concave parts 42a in two places on one side adjacent to the first transfer gate portion 13b having the first transfer electrode 25. Each concave part 42a takes a shape in which the length Wrx (width) in the X (+) direction spreads toward the Y(+) direction.

The shield layer for light sensing layer 42 having such plurality of concave parts 42a covers the light sensing layer 19 so as to expose a part of the light sensing layer 19 from inside of each of the concave parts 42a. The shield layer for light sensing layer 42 is provided so as to cause a partial area adjacent to each of the concave parts 42a to jut out into the first transfer gate portion 13b.

For example, in a case where a width Ws of the light sensing layer 19 is 10 μm, the shield layer for light sensing layer 42 is provided so as to cause a distance L between one end of the light sensing layer 19 and a bottom side 42a-1 of the concave part 42a, i.e., a distance L between one end of the N type impurity layer and one end of the P type impurity layer to become 0.8 μm.

By the way, although illustration is omitted, each of the first, third and fourth pixel portions in the solid-state imaging device according to the second embodiment also has a configuration similar to that shown in FIG. 9.

Even in a case where a plurality of concave parts 42a are provided in the shield layer for light sensing layer 42 in this way, a variation of an area of the light sensing layer 19 exposed between the shield layer for light sensing layer 42 and the first transfer gate portions 13a to 13d in a case where the light sensing layer 19 and the shield layer for light sensing layer 42 deviate from ideal positions due to, for example, a manufacture error can be made smaller than that in the conventional solid-state imaging device. In other words, it is possible to prevent a barrier or a dip from being generated in the electric potential between the light sensing layer 19 and the first transfer gate portions 13a to 13d.

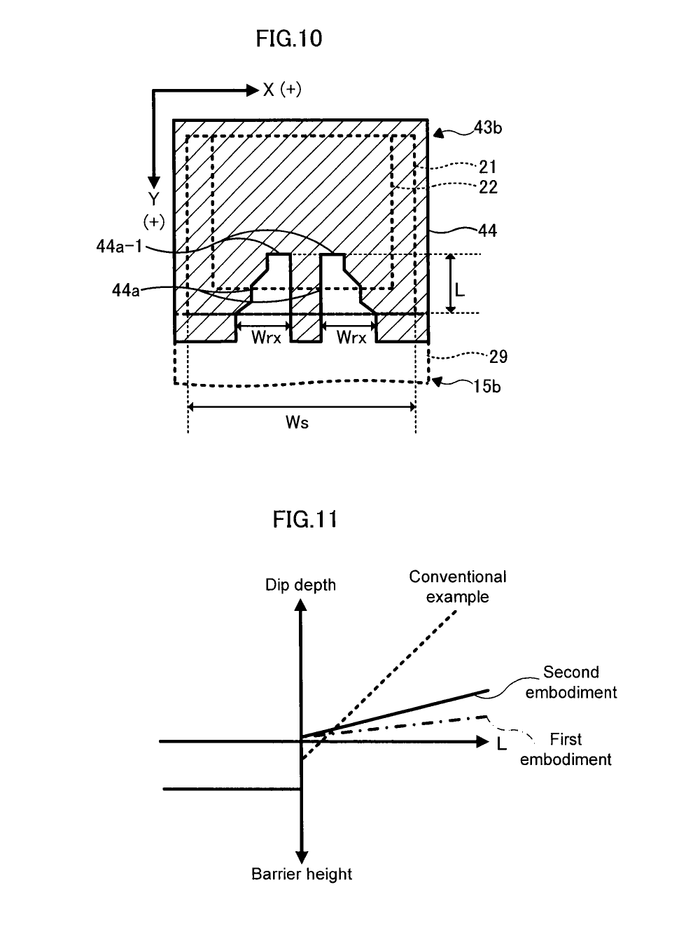

FIG. 10 is an enlarged plane view showing a second charge storage portion 43b in the solid-state imaging device according to the second embodiment. As shown in FIG. 10, the solid-state imaging device according to the second embodiment is the same as the solid-state imaging device 10 according to the first embodiment in that a shield layer for charge storage layer 44 takes the shape of a polygon that is nearly a rectangle corresponding to the shapes of the first and second charge storage layers 21 and 22. However, the solid-state imaging device according to the second embodiment is different from the solid-state imaging device 10 according to the first embodiment in that the shield layer for charge storage layer 44 has concave parts 44a in two places on one side adjacent to the second transfer gate portion 15b having the second transfer electrode 29 in the same way as the shield layer for light sensing layer 42 shown in FIG. 9. In the same way as the concave part 42a in the shield layer for light sensing layer 42, each concave part 44a also takes a shape in which the length Wrx (width) in the X(+) direction spreads toward the Y(+) direction.

The shield layer for charge storage layer 44 having such plurality of concave parts 44a covers the first and second charge storage layers 21 and 22 so as to expose parts of the first and second charge storage layers 21 and 22 from inside of each of the concave parts 44a. The shield layer for charge storage layer 44 is provided so as to cause partial areas adjacent to the concave parts 44a to jut out into the second transfer gate portion 15b.

For example, in a case where a width Ws of the first charge storage layer 21 is 10 μm, the shield layer for charge storage layer 44 is provided so as to cause a distance L between one end of the first charge storage layer 21 and a bottom side 44a-1 of the concave part 44a, i.e., a distance L between one end of the N type impurity layer and one end of the P type impurity layer to become 0.8 μm.

By the way, although illustration is omitted, the third charge storage portion in the solid-state imaging device according to the second embodiment also has a configuration similar to that shown in FIG. 10. Furthermore, the first and fourth charge storage portions have a configuration that is basically the same as that shown in FIG. 10 except that the first and second charge storage layers are provided in oblique directions from the first transfer gate portions 13a and 13d toward the second transfer gate portions 15a and 15d, respectively.

Even in a case where a plurality of concave parts 44a are provided in the shield layer for charge storage layer 44 in this way, a variation of an area of the first and second charge storage layers 21 and exposed between the shield layer for charge storage layer 44 and the second transfer gate portions 15a to 15d in a case where the first and second charge storage layers 21 and 22 and the shield layer for charge storage layer 44 deviate from ideal positions due to, for example, a manufacture error can be made smaller than that in the conventional solid-state imaging device. In other words, it is possible to prevent a barrier or a dip from being generated in the electric potential between the first charge storage layer 21 and the second transfer gate portions 15a to 15d.

FIG. 11 is a diagram showing relations between the distance L from the first end of the N type impurity layer to the first end of the P type impurity layer and a variation amount of an electric potential between the N type impurity layer and the transfer gate portion, in the solid-state imaging device according to the first and second embodiments and the conventional solid-state imaging device. The foregoing description is summarized in FIG. 11.

As shown in FIG. 11, inclination of a straight line (indicated by a solid line in FIG. 11) indicating relations between the distance L and the variation amount of the electric potential in the solid-state imaging device according to the second embodiment can be made smaller as compared with the conventional solid-state imaging device. In other words, it is possible to prevent a barrier or a dip from occurring in an electric potential between the light sensing layer 19 and the first transfer gate portion 13a to 13d and the electric potential between the first charge storage layer 21 and the second transfer gate portion 15a to 15d. As a result, it is possible to lower the voltage applied to the transfer gate portions 13a to 13d and 15a to 15d and expand the voltage margin of the voltage applied to the transfer gate portions 13a to 13d and 15a to 15d when transferring charge from respective pixel portions including the second pixel portion 41b to the first transfer gate portions 13a to 13d and when transferring charge from respective charge storage portions including the second charge storage portion 43 to the second transfer gate portions 15a to 15d. Furthermore, it is facilitated to satisfy a voltage margin demanded for each product and the yield is improved.

In the solid-state imaging device according to the present embodiment as well, concave parts 42a and 44a are provided in the shield layer for light sensing layer 42 and the shield layer for charge storage layer 44, respectively, in the same way as the solid-state imaging device 10 according to the first embodiment as described heretofore. Therefore, voltage margins of the voltages applied to the transfer gate portions 13a to 13d and 15a to 15d can be expanded and the yield can be improved. Furthermore, especially since the voltage margin can be expanded, voltages applied to the transfer gate portions 13a to 13d and 15a to 15d can be made low and the charge transfer speed can be made fast.

In addition, the concave parts 42a and 44a are provided so as to cause the width Wrx of the concave parts 42a in the shield layer for light sensing layer 42 and the width Wrx of the concave parts 44a in the shield layer for charge storage layer to spread toward the Y(+) direction, i.e., the charge transfer direction. Therefore, it is possible to improve the charge transfer efficiency from each pixel portion to the first transfer gate portions 13a to 13d, and the charge transfer efficiency from each charge storage portion to the second transfer gate portions 15a to 15d.

By the way, in the solid-state imaging device according to the second embodiment, the concave parts 42a are provided in two places of the shield layer for light sensing layer 42 and the concave parts 44a are provided in two places in the shield layer for charge storage layer 44. Therefore, an area of the light sensing layer 19 exposed from the concave parts 42a in the two places and an area of the first and second charge storage layers 21 and 22 exposed from the concave parts 44a in the two places becomes wider as compared with the solid-state imaging device 10 according to the first embodiment. As a result, the variation amount of the electric potential due to a manufacture error becomes larger as compared with the solid-state imaging device 10 according to the first embodiment (FIG. 11). In the solid-state imaging device according to the second embodiment, however, the concave parts 42a are provided in two places and the concave parts 44a are provided in two places. Therefore, it is possible to cause the charge transfer speed from each pixel portion to the first transfer gate portion 13a to 13d and the charge transfer speed from each charge storage portion to the second transfer gate portion 15a to 15d to become approximately twice as compared with the solid-state imaging device 10 according to the first embodiment.

### Third Embodiment

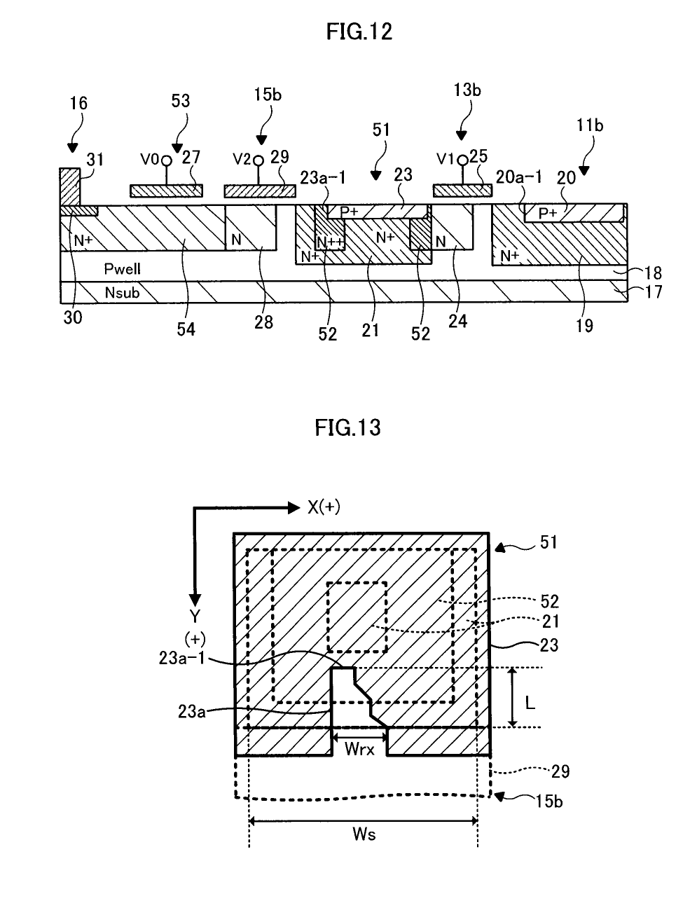

A solid-state imaging device according to a third embodiment will now be described. FIG. 12 is a sectional view corresponding to FIG. 2, in a solid-state imaging device according to a third embodiment. By the way, a plane view of a solid-state imaging device according to the third embodiment is similar to FIG. 1.

The solid-state imaging device shown in FIG. 12 differs from the solid-state imaging device 10 according to the first embodiment shown in FIG. 2 in structures of a second charge storage layer 52 in a second charge storage portion 51 and an offset gate layer 54 in an offset gate portion 53. Hereafter, the second charge storage portion 51 and the offset gate portion 53 will be described. The same structure as that in the solid-state imaging device 10 according to the first embodiment is denoted by like reference numeral in the solid-state imaging device 10 according to the first embodiment, and description thereof will be omitted.

First, the second charge storage portion 51 will be described. In the second charge storage portion 51, the second charge storage layer 52 is provided on a part of the surface of the first charge storage layer 21 so as to be away from the second transfer gate portion 15b. The second charge storage layer 52 is, for example, an N++ type impurity layer that is higher in concentration than the first charge storage layer 21.

FIG. 13 is an enlarged plane view showing the second charge storage portion 51 and its periphery. As shown in FIG. 13, the second charge storage layer 52 is provided in a ring form on the surface of the first charge storage layer 21.

The shield layer for charge storage layer 23 is provided on the surface of the first charge storage layer 21 inclusive of the ring-shaped second charge storage layer 52.

By the way, although illustration is omitted, a second charge storage layer in the third charge storage portion is also provided in a ring form in the same way in a solid-state imaging device according to the third embodiment. However, a second charge storage layer in each of the first and fourth charge storage portions is not provided in a ring form, but provided in a plane form. However, the second charge storage layers in the first and fourth charge storage portions are provided so as to spread in width from the first transfer gate portions 13a and 13d toward the second transfer gate portions 15a and 15d, respectively.

The offset gate portion 53 will now be described. As shown in FIG. 12, the offset gate layer 54 in the offset gate portion 53 is, for example, an N+ type impurity layer. The offset gate layer 54 is provided in a wide range including the offset gate portion 54 and the charge detection portion 16 so as to be away from the second transfer gate portion 15b.

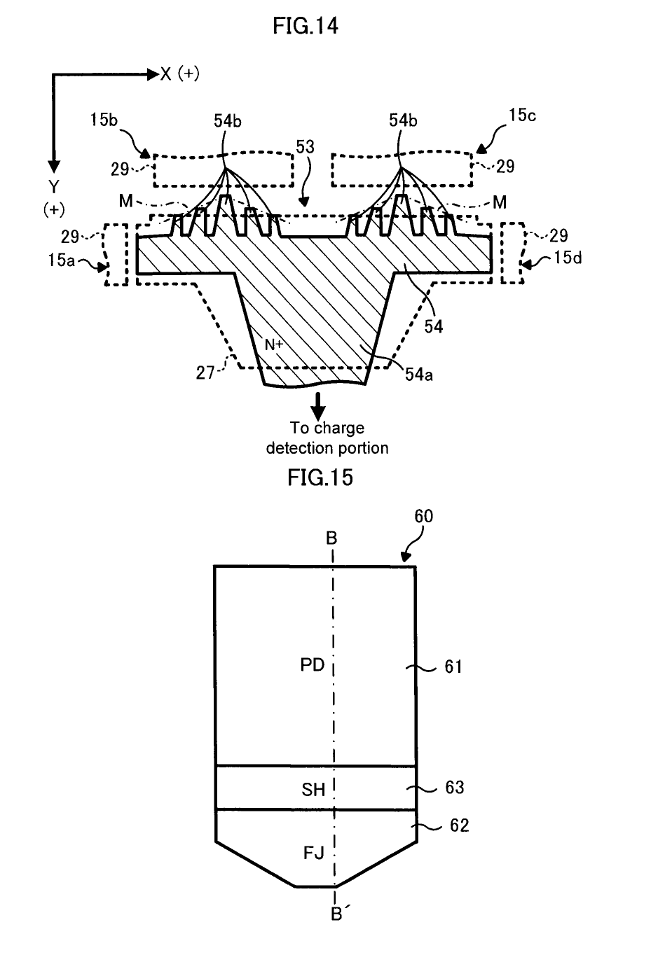

FIG. 14 is an enlarged plane view showing the offset gate portion 53 and its periphery. By the way, in FIG. 14, each of the offset gate electrode 27 and the second transfer electrode 29 is indicated by a dashed line. As shown in FIG. 14, the offset gate layer 54 takes a convex shape. The offset gate layer 54 is provided to have a convex part 54a facing the charge detection portion 16. In the offset gate layer 54, long side parts opposed to the convex part 54a (areas adjacent to the second transfer gate portions 15b and 15c) take the shape of a comb. In other words, on one side of the offset gate layer 54 parallel to the lengthwise direction (X direction) of the pixel portions 11a, 11b, 11c and 11d, a plurality of projection parts 54b are provided away from each other. The plurality of projection parts 54b are provided for each of the second transfer portions 15b and 15c. For example, a plurality of projection portions 54b in close to the second transfer gate portion 15b differ from each other in length so as to form a mountain shape with straight lines M coupling tips of the projection portions. A plurality of projection portions 54b in close to the third transfer gate portion 15c also differ from each other in length.

In the solid-state imaging device according to the third embodiment including the second charge storage portion 51 and the offset gate portion 53 as well, the concave parts 20a and 23a as shown in FIG. 4, FIG. 5 and FIG. 13 are provided respectively in the shield layer for light sensing layer 20 and the shield layer for charge storage layer 23 in the same way as the solid-state imaging device 10 according to the first embodiment. Therefore, voltage margins of the voltages applied to the transfer gate portions 13a to 13d and 15a to 15d can be expanded and the yield can be improved. Furthermore, especially since the voltage margin can be expanded, voltages applied to the transfer gate portions 13a to 13d and 15a to 15d can be made low and the charge transfer speed can be made fast.

In addition, in the solid-state imaging device according to the present embodiment as well, the concave parts 20a and 23a are provided so as to cause each of the width Wrx of the concave part 20a in the shield layer for light sensing layer 20 and the width Wrx of the concave part 23a in the shield layer for charge storage layer 23 to spread toward the Y(+) direction, i.e., toward the charge transfer direction. Therefore, the charge transfer efficiency in each area can be improved.

Furthermore, in the solid-state imaging device according to the present embodiment, the second charge storage layer 52 in the second charge storage portion 51 is provided in the ring form and in addition the second charge storage layer in the third charge storage portion is also provided in the ring form in the same way. In addition, a partial area of the offset gate layer 54 in the offset gate portion 53 is provided in a comb form. As a result, the charge transfer speed from respective pixels 11a to 11d to the charge detection portion 16 can be improved.

The solid-state imaging devices according to the first to third embodiments relate to CCD image sensors. However, the present invention can be applied to CMOS image sensors as well.

### Fourth Embodiment

FIG. 15 is a plane view schematically showing a principal part of a solid-state imaging device according to a fourth embodiment. By the way, the solid-state imaging device shown in FIG. 15 is a part of a CMOS image sensor. An actual CMOS image sensor is formed by arranging a plurality of structures each shown in FIG. 15, in a lattice form.

In a solid-state imaging device 60, a transfer gate portion (SH) 63 is formed between a pixel portion (PD) 61 and a charge detection portion (FJ) 62 as shown in FIG. 15. The pixel portion 61 and the charge detection portion 62 operate in the same way as the pixel portions 11a to 11d and the charge detection portion 16 in the solid-state imaging devices according to the first to third embodiments. On the other hand, the transfer gate portion (SH) 63 reads out charge generated in the pixel portion 61 and transfers the charge read out to the charge detection portion 62.

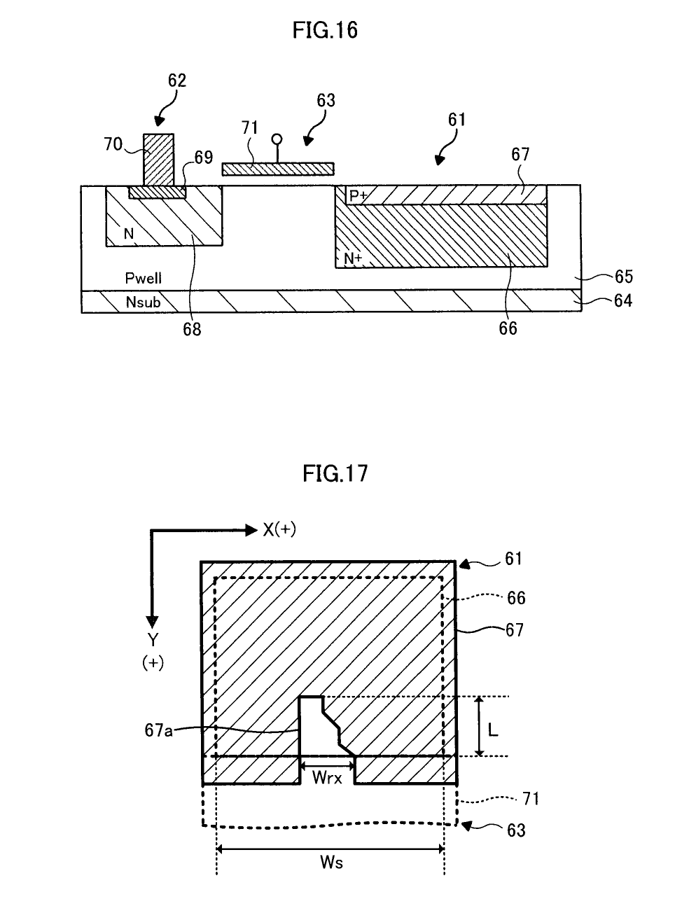

FIG. 16 is a sectional view of the solid-state imaging device 60 taken along a dot-dash line B-B′ in FIG. 15. As shown in FIG. 16, the pixel portion 61, the transfer gate portion 63, and the charge detection portion 62 are provided on or over, for example, a P type well layer 65 provided on an N type semiconductor substrate 64.

In the pixel portion 61, a light sensing layer 66, which is, for example, an N+ type impurity layer is provided on a surface of the well layer 65. Furthermore, a shield layer for light sensing layer 67 is provided on a surface of the light sensing layer 66 to shield the light sensing layer 66. The shield layer for light sensing layer 67 is, for example, a P+ type impurity layer. Furthermore, it is also possible to provide an N type well layer 65 on a P type semiconductor substrate 64.

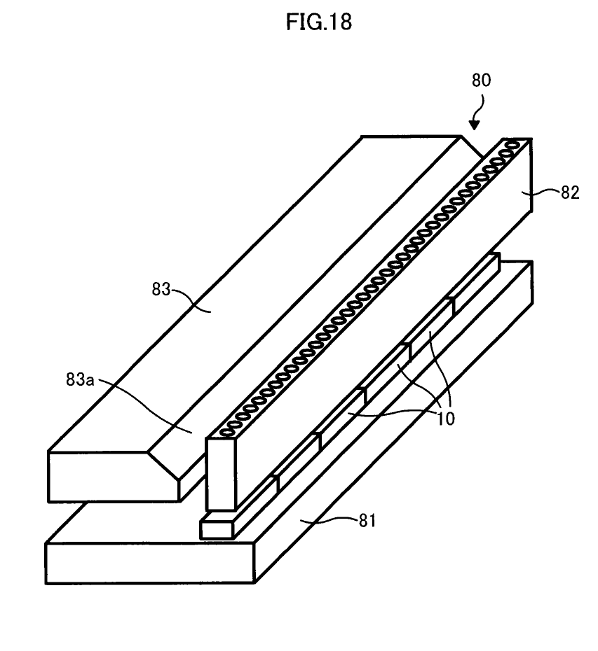

FIG. 17 is an enlarged plane view of the pixel portion 61. In FIG. 17, each of the light sensing layer 66 and a transfer electrode 71 which will be described later is indicated a dashed line. As shown in FIG. 17, the shield layer for light sensing layer takes a shape of a polygon, which is nearly a rectangle, corresponding to a shape of the light sensing layer 66. The shield layer for light sensing layer 67 has a concave part 67a on one side adjacent to the transfer gate portion 63 having the transfer electrode 71. The concave part 67a takes a shape in which a length Wrx (width) in the X(+) direction spreads toward the Y(+) direction.

The shield layer for light sensing layer 67 having the concave part 67a covers the light sensing layer 66 so as to expose a part of the light sensing layer 66 from inside of the concave part 67a. The shield layer for light sensing layer 67 is provided so as to cause a partial area adjacent to the concave part 67a to jut out into the transfer gate portion 63.

In other words, the pixel portion 61 is configured in the same way as each of the pixel portions 11a to 11d in the solid-state imaging device 10 according to the first embodiment.

In the charge detection portion 62 shown in FIG. 16, a first charge detection layer 68 which is, for example, an N type impurity layer is provided on the surface of the well layer 65. A second charge detection layer 69 which is an impurity layer that is higher in concentration than the first charge detection layer 68 is provided on a part of a surface of the first charge detection layer 68. Furthermore, a read electrode 70 is provided on a surface of the second charge detection layer 69.

In the transfer gate portion 63 between the pixel portion 61 and the charge detection portion 62, a transfer electrode 71 is provided on the surface of the well layer 65.

By the way, in the solid-state imaging device 60 according to the present embodiment, the offset gate portion is not provided. However, the offset gate portion may be provided between the transfer gate portion 63 and the charge detection portion 62.

The solid-state imaging device 60 also operates basically in the same way as the solid-state imaging devices according to the first to third embodiments. In other words, charge generated in the pixel portion 61 is transferred to the charge detection portion 62 by applying a predetermined voltage to the transfer electrode 71 and making the transfer gate portion 63 deeper in electric potential than the pixel portion 61. The charge transferred to the charge detection portion 62 drops the electric potential in the charge detection portion 62. This voltage drop is read out as a signal voltage by the read electrode 70. The solid-state imaging device 60 forms an image on the basis of the signal voltage read out in this way.

In the solid-state imaging device 60 according to the fourth embodiment as well, the concave part 67a as shown in FIG. 17 is provided in the shield layer for light sensing layer 67 in the same way as the solid-state imaging device 10 according to the first embodiment. Therefore, a voltage margin of a voltage applied to the transfer gate portion 63 can be expanded and the yield can be improved. Furthermore, especially since the voltage margin can be expanded, the voltage applied to the transfer gate portion 63 can be made low and the charge transfer speed can be made fast.

In addition, in the solid-state imaging device 60 according to the present embodiment as well, the concave part 67a is provided so as to cause the width Wrx of the concave part 67a in the shield layer for light sensing layer 67 to spread toward the Y(+) direction, i.e., toward the charge transfer direction. Therefore, the charge transfer efficiency can be improved.

The solid-state imaging devices according to the first to fourth embodiments described heretofore are applied to, for example, a line sensor. Hereafter, a line sensor with, for example, the solid-state imaging device 10 according to the first embodiment applied thereto will be described as an application example.

### Application Example

FIG. 18 is an oblique view showing a line sensor to which the solid-state imaging device 10 according to the first embodiment is applied. A line sensor 80 includes a circuit substrate 81, a plurality of solid-state imaging devices 10, a SELFOC lens array 82, and a light guide plate 83. Although illustration is omitted, they are disposed in a case.

The plurality of solid-state imaging devices 10 are disposed adjacent to each other on the circuit substrate 81 in a straight line form. The solid-state imaging devices 10 are disposed on the circuit substrate 81 with light sensing planes of the solid-state imaging devices 10 being opposed to an output plane of the SELFOC lens array 82. The solid-state imaging devices 10 are connected electrically to interconnections provided on the circuit substrate 81.

By the way, although illustration is omitted, the circuit substrate 81 includes an image processing circuit which forms an image on the basis of signal voltages output from respective solid-state imaging devices 10.

The SELFOC lens array 82 and the light guide plate 83 are disposed above the circuit substrate 81 and supported by a case (not illustrated). The light guide plate 83 includes an emission plane 83a for emitting light emitted from a light source (not illustrated) such as an LED disposed on an end part toward a copy.

The SELFOC lens array 82 is disposed above the circuit substrate 81 to receive light reflected by a copy and cause the solid-state imaging devices 10 to form an image. Therefore, light emitted from the emission plane 83a of the light guide plate 83 is reflected by the copy, and then incident on the SELFOC lens array 82. An image is formed by the solid-state imaging devices 10.

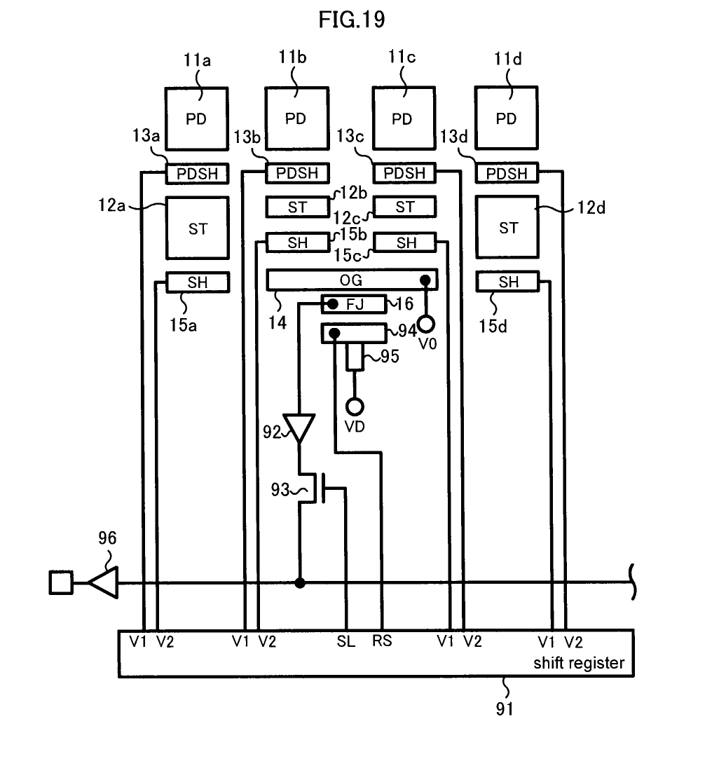

FIG. 19 shows a circuit block diagram of one solid-state imaging device 10 applied to the line sensor 80. By the way, the circuit block diagram shown in FIG. 19 is a circuit block diagram corresponding to one cell provided in the solid-state imaging device 10. In the actual solid-state imaging device, the circuit block shown in FIG. 19 is arranged.

As shown in FIG. 19, first transfer gate portions 13a to 13d and second transfer gate portions 15a to 15d are connected to a shift register 91. A gate pulse V1 output from the shift register 91 is input to the first transfer gate portions 13a to 13d at desired timing. A gate pulse V2 output from the shift register 91 is input to the second transfer gate portions 15a to 15d at desired timing.

For example, if the gate pulse V1 is input to the four first transfer gate portions 13a to 13d at the same timing and the gate pulse V2 is input to the four second transfer gate portions 15a to 15d at the same timing, all charge generated in the pixel portions 11a to 11d are transferred to the charge detection portion 16 and stored therein. As a result, the four pixel portions 11a to 11d can be regarded as one pixel, and consequently the sensitivity of the cell is made high.

On the other hand, if the gate pulse V1 is input to the four first transfer gate portions 13a to 13d at different timing and the gate pulse V2 is input to the four second transfer gate portions 15a to 15d at different timing, charges generated in the pixel portions 11a to 11d are transferred to the charge detection portion 16 at different timing and stored. As a result, the four pixel portions 11a to 11d can be regarded as different pixel portions, and consequently the resolution of the cell is made high.

In other words, in this solid-state imaging device, the sensitivity and resolution of the cell can be changed over by controlling timing of applying the gate pulse V1 and the gate pulse V2.

Furthermore, a transistor 93 is connected to the charge detection portion 16 via an amplifier 92. The transistor 93 is a selection transistor for selecting one cell out of a plurality of cell arranged in the solid-state imaging device 10. A gate of the selection transistor 93 is connected to a shift register 91. A selection pulse SL output from the shift register 91 is input to the gate of the selection transistor 93 at desired timing.

In addition, a reset gate portion 94 and a drain 95 applied with a constant voltage VD are connected to the charge detection portion 16 in the cited order. The reset gate portion 94 is a gate for transferring unnecessary charge stored in the charge detection portion 16 to the drain 95 and resetting the charge detection portion 16. The reset gate portion 94 is connected to the shift register 91. A reset pulse RS output from the shift register 91 is input to the reset gate portion 94 at desired timing.

If charge is stored in the charge detection portion 16 in the solid-state imaging device, a signal voltage detected in the charge detection portion 16 is input to the selection transistor 93. If the selection pulse SL from the shift register 91 is input to the gate of the selection transistor 93 in this state, the signal voltage input to the selection transistor 93 is input to an amplifier 96 via the selection transistor 93. The signal voltage is amplified in power and output as an image signal.

On the other hand, unnecessary charge stored in the charge detection portion 16 after the signal voltage is detected in the charge detection portion 16 is transferred to the drain 95 when the reset gate portion 94 is turned on by the reset pulse RS input from the shift register 91 to the reset gate portion 94. As a result, the charge detection portion 16 is reset.

Each of the solid-state imaging devices 10 provided in the line sensor 80 shown in FIG. 18 generates an image signal by causing cells provided in the device to conduct operation described with reference to FIG. 19. The generated image signal is sent to the circuit substrate 81. An image processing circuit provided on the circuit substrate 81 forms an image. The line sensor 80 forms an image in this way.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the number of the concave parts provided in the shield layer for light sensing layer and the number of the concave parts provided in the shield layer for charge storage layer is not restricted to one place or two places, but the concave parts may be provided in a plurality of places which are at least three places.

Furthermore, the solid-state imaging device according to each of the above-described embodiments is provided on the P type well layer 18 or 65 provided on the N type semiconductor substrate 17 or 64. However, the solid-state imaging device need not necessarily be provided on the well layer 18 or 65, but may be provided on a P type semiconductor substrate.

What is claimed is:

1. A solid-state imaging device comprising:
a pixel portion including a light sensing layer provided on a surface of a semiconductor substrate to generate charge depending upon a light sensing amount of incident light, and a shield layer for the light sensing layer provided so as to shield the light sensing layer;
a charge storage portion including a charge storage layer provided on the surface of the semiconductor substrate to store the charge generated in the pixel portion and a shield layer for the charge storage layer provided so as to shield the charge storage layer;
a first transfer gate portion reading out the charge from the pixel portion and transferring the charge to the charge storage portion;
a charge detection portion to which the charge stored in the charge storage portion is transferred and which generates a voltage drop depending upon a charge amount of the transferred charge; and
a second transfer gate portion reading out the charge stored in the charge storage portion and transferring the charge to the charge detection portion,
wherein at least one of the shield layer for the light sensing layer and the shield layer for the charge storage layer has a concave part to expose a part of the light sensing layer adjacent to the first transfer gate portion, or a part of the charge storage layer adjacent to the second transfer gate portion.

2. The solid-state imaging device according to claim 1, wherein each of the shield layer for light sensing layer and the shield layer for charge storage layer has the concave part.

3. The solid-state imaging device according to claim 2, wherein a width of the concave part becomes wider toward a transfer direction of the charge.

4. The solid-state imaging device according to claim 1, wherein at least one of the shield layer for light sensing layer and the shield layer for charge storage layer has a plurality of the concave parts.

5. The solid-state imaging device according to claim 4, wherein each of the shield layer for light sensing layer and the shield layer for charge storage layer has a plurality of the concave parts.

6. The solid-state imaging device according to claim 5, wherein a width of each of the plurality of the concave parts becomes wider in width toward a transfer direction of the charge.

7. The solid-state imaging device according to claim 1, comprising
a plurality of the pixel portions, a plurality of the charge storage portions, a plurality of the first transfer gate portions, a plurality of the second transfer gate portions, and an offset gate portion,
wherein the plurality of the pixel portions are arranged in a row form, wherein each of the plurality of pixel portions takes a shape having a lengthwise direction aligned with a direction of arrangement of the plurality of pixel portions,
the plurality of charge storage portions arranged in a row form parallel to a direction of arrangement of the pixel portions, and
the offset gate portion takes a shape having a long side along a lengthwise direction which is a direction parallel to the direction of arrangement of the plurality of pixel portions and a short side along a direction substantially perpendicular to the lengthwise direction, wherein the offset gate portion is provided between the plurality of second transfer gate portions and the charge detection portion so as to be close to the plurality of second transfer gate portions at the long side and the short side, and is applied with a predetermined constant voltage.

8. The solid-state imaging device according to claim 7, wherein
the offset gate portion comprises an offset gate layer provided on the surface of the semiconductor substrate, and an offset gate electrode provided on the surface of the semiconductor substrate inclusive of the offset gate layer, and
the offset gate layer has a plurality of projection parts in positions corresponding to the long side of the offset gate portion.

9. The solid-state imaging device according to claim 8, wherein the plurality of projection portions are provided every second transfer gate portion.

10. The solid-state imaging device according to claim 7, wherein a second charge storage layer taking a shape of a ring is further provided on a surface of the first charge storage layer in at least one of the charge storage portions.

11. A solid-state imaging device comprising:
a pixel portion including a light sensing layer provided on a surface of a semiconductor substrate to generate charge depending upon a light sensing amount of incident light and a shield layer for light sensing layer provided so as to shield the light sensing layer;
a charge detection portion to which the charge stored in the pixel portion is transferred and which generates a voltage drop depending upon a charge amount of the transferred charge; and
a transfer gate portion reading out the charge stored in the pixel portion and transferring the charge to the charge detection portion,
wherein the shield layer for light sensing layer has a concave part to expose a part of the light sensing layer adjacent to the transfer gate portion.

12. The solid-state imaging device according to claim 11, wherein the shield layer for light sensing layer has a plurality of the concave parts.

13. The solid-state imaging device according to claim 12, wherein a width of the concave part becomes wider toward the charge transfer direction.

14. A line sensor comprising:
a circuit substrate;
a plurality of solid-state imaging devices arranged in a straight line form on a surface of the circuit substrate;
a light guide plate disposed above the surface of the circuit substrate to emit light toward a subject; and
a lens array disposed above the surface of the circuit substrate to converge the light reflected from the subject to the plurality of solid-state imaging devices,
wherein each of the plurality of solid-state imaging devices comprises
a pixel portion including a light sensing layer provided on a surface of a semiconductor substrate to generate charge depending upon a light sensing amount of incident light, and a shield layer for light sensing layer provided so as to shield the light sensing layer;
a charge storage portion including a charge storage layer provided on the surface of the semiconductor substrate to store the charge generated in the pixel portion and a shield layer for charge storage layer provided so as to shield the charge storage layer;
a first transfer gate portion reading out the charge from the pixel portion and transferring the charge to the charge storage portion;
a charge detection portion to which the charge stored in the charge storage portion is transferred and which generates a voltage drop depending upon a charge amount of the transferred charge; and
a second transfer gate portion reading out the charge stored in the charge storage portion and transferring the charge to the charge detection portion, and
at least one of the shield layer for light sensing layer and the shield layer for charge storage layer has a concave part to expose a part of the light sensing layer adjacent to the first transfer gate portion, or a part of the charge storage layer adjacent to the second transfer gate portion.
